(19) United States
(12) Patent Application Publication
(10) Pub. No.: US 2012/0074860 A1
(43) Pub. Date: Mar. 29, 2012

(54) Dimming Circuit, A Light Emitting Diode Driver Including The Same And A Light Emitting Diode Driver

(75) Inventor: Bum-Kil LEE, Seoul (KR)

(73) Assignee: Samsung Electronics Co., Ltd., Suwon-si (KR)

(21) Appl. No.: 13/223,763

(22) Filed: Sep. 1, 2011

(30) Foreign Application Priority Data
Sep. 28, 2010 (KR) 10-2010-0093512

(51) Int. Cl. H05B 37/02; H03C 3/00

(52) U.S. Cl. 315/240; 315/246; 332/117; 332/118

(57) ABSTRACT

The dimming circuit includes a reference signal generation unit, a frequency modulation unit and a duty cycle control unit. The reference signal generation unit generates a reference signal. The frequency modulation unit generates a frequency modulation signal having an initial frequency based on the reference signal and a control signal, repeatedly performs a counting operation that counts at least one pulse of the frequency modulation signal, and adjusts the frequency of the frequency modulation signal if the counting operation is completed. The duty cycle control unit generates a pulse width modulation (PWM) output signal by adjusting a duty cycle of the frequency modulation signal.

### CROSS-REFERENCE TO RELATED APPLICATIONS

This U.S. non-provisional application claims the benefit of priority under 35 U.S.C. §119 to Korean Patent Application No. 2010-0093512, filed on Sep. 28, 2010 in the Korean Intellectual Property Office (KIPO), the entire contents of which is incorporated herein by reference.

### BACKGROUND

1. Field

Example embodiments relate to dimming circuits. More particularly, example embodiments relate to dimming circuits included in light emitting diode (LED) drivers and LED drivers.

2. Description of the Related Art

A liquid crystal display (LCD) device displays an image by adjusting the amount of transmitted light using a characteristic of liquid crystals of which an arrangement of molecules varies according to an applied voltage. The LCD device may include a light source device, such as a back-light device. For example, the LCD device may employ a cold cathode fluorescent lamp (CCFL) and a hot cathode fluorescent lamp (HCFL) as the light source device. Recently, a light emitting diode (LED) has been widely used because the LED consumes less power and is mercury-free and eco-friendly. Various methods have been developed to adjust brightness of the LED, and a typical one of these methods adjusts the brightness of the LED based on a pulse width modulation (PWM) signal.

### SUMMARY

At least one example embodiment provides a dimming circuit included in an LED driver configured to reduce noise and improve performance.

At least one example embodiment provides an LED driver including a dimming circuit configured to reduce noise and improve performance.

According to at least one example embodiment, a dimming circuit included in a light emitting diode (LED) driver includes a reference signal generation unit, a frequency modulation unit and a duty cycle control unit. The reference signal generation unit may generate a reference signal for determining an initial frequency of a frequency modulation signal based on a control signal.

The frequency modulation may unit generate the frequency modulation signal having the initial frequency based on the reference signal, may repeatedly perform a counting operation that counts at least one pulse of the frequency modulation signal, and may adjust the frequency of the frequency modulation signal whenever the counting operation is completed. The duty cycle control unit may generate a pulse width modulation (PWM) output signal by adjusting a duty cycle of the frequency modulation signal.

In at least one example embodiment, the frequency modulation unit may include a counter unit configured to generate a digital count signal by performing the counting operation, and to adjust a value of the digital count signal whenever the counting operation is completed, a digital-to-analog conversion unit configured to convert the digital count signal into an analog count signal based on the reference signal, and an oscillation unit configured to generate the frequency modulation signal having the initial frequency based on the reference signal, and to adjust the frequency of the frequency modulation signal based on the reference signal and the analog count signal.

In at least one example embodiment, a level of the analog count signal may increase as the value of the digital count signal increases, and the frequency of the frequency modulation signal may increase as the level of the analog count signal increases. The level of the analog count signal may decrease as the value of the digital count signal decreases, and the frequency of the frequency modulation signal may decrease as the level of the analog count signal decreases.

In at least one example embodiment, the counter unit may include a counter control unit configured to perform the counting operation, and to generate an up count signal for increasing the value of the digital count signal or a down count signal for decreasing the value of the digital count signal whenever the counting operation is completed, and a counter configured to increase the value of the digital count signal in response to the up count signal, and to decrease the value of the digital count signal in response to the down count signal.

In at least one example embodiment, the digital count signal may have a maximum value and a minimum value, and the counter control unit may activate the up count signal until the value of the digital count signal reaches the maximum value, and, if the value of the digital count signal reaches the maximum value, may activate the down count signal until the value of the digital count signal reaches the minimum value.

In at least one example embodiment, the digital-to-analog conversion unit may include a plurality of bit current generation units configured to generate a plurality of bit current signals, respectively, each bit current generation unit may generate a corresponding one of the plurality of bit current signals based on a corresponding one of a plurality of bits of the digital count signal, and an output node configured to provide the analog count signal by adding the plurality of bit current signals.

In at least one example embodiment, a level of each bit current signal may be exponentially proportional to an order of the corresponding one of the plurality of bits of the digital count signal. In at least one example embodiment, the each bit current generation unit may include a transistor including a first electrode coupled to a power supply voltage, a gate coupled to the reference signal generation unit, and a second electrode, the transistor forming a current mirror with the reference signal generation unit, and a switch configured to selectively couple the second electrode of the transistor to the output node according to a logic level of the corresponding one of the plurality of bits of the digital count signal.

In at least one example embodiment, the oscillation unit may include an initial frequency signal generation unit configured to generate an initial frequency signal based on the reference signal, a saw signal generation unit configured to generate a saw signal based on the initial frequency signal, the analog count signal and the frequency modulation signal, and a frequency modulation signal generation unit configured to generate the frequency modulation signal based on the saw signal and a bias signal.

In at least one example embodiment, the initial frequency signal generation unit may include a transistor including a first electrode coupled to a power supply voltage, a gate coupled to the reference signal generation unit, and a second electrode, the transistor forming a current mirror with the reference signal generation unit.

In at least one example embodiment, the saw signal generation unit may include a capacitor including a first terminal coupled to the second electrode of the transistor and a second terminal to a ground voltage, and a switch configured to selectively couple the first terminal of the capacitor to the ground voltage based on the frequency modulation signal.

In at least one example embodiment, the frequency modulation signal generation unit may include a comparator configured to compare the saw signal and the bias signal, and to generate the frequency modulation signal having a first logic level while the saw signal is lower than the bias signal and a second logic level while the saw signal is equal to or greater than the bias signal.

In at least one example embodiment, the oscillation unit may further include a buffer unit configured to buffer the frequency modulation signal, and to output the buffered frequency modulation signal. In at least one example embodiment, the reference signal generation unit may include a first transistor including a first electrode coupled to a power supply voltage, and a gate and a second electrode that are coupled to each other, a comparator including a first input terminal to which a regulation voltage is applied, a second input terminal, and an output terminal, a second transistor including a third electrode coupled to the second electrode of the first transistor, a gate coupled to the output terminal of the comparator, and a fourth electrode coupled to the second input terminal of the comparator, and a variable resistor coupled between the fourth electrode of the second transistor and a ground voltage, the variable resistor having a resistance that varies in response to the control signal.

According to at least one example embodiment, a light emitting diode (LED) driver may include a dimming circuit and a current control circuit. The dimming circuit may generate a pulse width modulation (PWM) output signal having a variable frequency. The current control circuit may control a current that flows through LEDs based on the PWM output signal. The dimming circuit may include a reference signal generation unit configured to generate a reference signal for determining an initial frequency of a frequency modulation signal based on a control signal, a frequency modulation unit configured to generate the frequency modulation signal having the initial frequency based on the reference signal, to repeatedly perform a counting operation that counts at least one pulse of the frequency modulation signal, and to adjust the frequency of the frequency modulation signal whenever the counting operation is completed, and a duty cycle control unit configured to generate the PWM output signal by adjusting a duty cycle of the frequency modulation signal.

As described above, a dimming circuit included in an LED driver according to example embodiments may generate a frequency modulation signal having a variable frequency that is adjusted whenever each counting operation is completed, and generates a PWM output signal having the variable frequency based on the frequency modulation signal, thereby improving an EMI characteristic of the LED driver, reducing an audible noise, and improving performance of the LED driver.

### BRIEF DESCRIPTION OF THE DRAWINGS

Example embodiments will be more clearly understood from the following brief description taken in conjunction with the accompanying drawings. FIGS. 1-13 represent non-limiting, example embodiments as described herein.

FIG. 1 is a block diagram illustrating a dimming circuit included in an LED driver according to example embodiments.

FIG. 2 is a circuit diagram illustrating an example of a reference signal generation unit included in a dimming circuit of FIG. 1.

FIG. 3 is a block diagram illustrating an example of a frequency modulation unit included in a dimming circuit of FIG. 1.

FIG. 4 is a diagram illustrating another example of a frequency modulation unit included in a dimming circuit of FIG. 1.

FIG. 5 is a diagram illustrating an example of an N-bit counter unit included in a counter unit illustrated in FIG. 4.

FIG. 6 is a diagram illustrating still another example of a frequency modulation unit included in a dimming circuit of FIG. 1.

FIG. 7 is a timing diagram illustrating an operation of a dimming circuit according to example embodiments.

FIG. 8 is a graph illustrating a change in a frequency of a PWM output signal output from a dimming circuit over time according to example embodiments.

FIGS. 9 and 10 are graphs illustrating an example of a spectral distribution of a noise signal included in a PWM output signal output from a dimming circuit according to example embodiments.

FIG. 11 is a graph illustrating an equal loudness curve according to a frequency.

FIG. 12 is a block diagram illustrating an LED light source device including a dimming circuit according to example embodiments.

FIG. 13 is a block diagram illustrating a display device including an LED light source device according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF THE EMBODIMENTS

Various example embodiments will be described more fully hereinafter with reference to the accompanying drawings, in which some example embodiments are shown.

The present inventive concept may, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a block diagram illustrating a dimming circuit included in a light emitting diode (LED) driver according to at least one example embodiment.

Referring to FIG. 1, a dimming circuit 1000 for an LED driver may include a reference signal generation unit 1100, a frequency modulation unit 1200 and a duty cycle control unit 1300. The reference signal generation unit 1100 may generate a reference signal REF for determining an initial frequency of a frequency modulation signal FMS based on a control signal CON. In at least one example embodiment, the reference signal REF may be a current signal or a voltage signal. The control signal CON may be provided from an internal circuit of the LED driver including the dimming circuit 1000, or may be provided from an external circuit.

The frequency modulation unit 1200 may generate a frequency modulation signal FMS having the initial frequency based on the reference signal REF. The frequency modulation unit 1200 may repeatedly count at least one pulse of the frequency modulation signal FMS, and may adjust the frequency of the frequency modulation signal FMS whenever the counting operation is completed. As illustrated in FIG. 1, the frequency modulation unit 1200 may output the frequency modulation signal FMS, and may receive as feedback the output frequency modulation signal FMS to count the pulses of the output frequency modulation signal FMS.

In at least one example embodiment, the frequency modulation unit 1200 may perform each counting operation such that a desired (or, alternatively, a predetermined) number of pulses of the frequency modulation signal FMS are counted. Accordingly, the frequency modulation unit 1200 may adjust the frequency of the frequency modulation signal FMS after every desired (or, alternatively, a predetermined) number of pulses of the frequency modulation signal FMS. That is, the frequency of the frequency modulation signal FMS (i.e., the period of the frequency modulation signal FMS) may be increased or decreased after every desired, (or, alternatively, predetermined) number of pulses. For example, if the desired number is 2, the frequency modulation unit 1200 may increase or decrease the frequency of the frequency modulation signal FMS whenever two successive pulses of the frequency modulation signal FMS are counted.

In at least one example embodiment, the frequency modulation unit 1200 may periodically perform each counting operation with a fixed period. And thus, the frequency modulation unit 1200 may adjust the frequency of the frequency modulation signal FMS according to the number of counted pulses of the frequency modulation signal FMS. The frequency modulation unit 1200 may adjust the frequency of the frequency modulation signal FMS proportional to the number of the counted pulses. For example, the frequency modulation unit 1200 may compare the number of currently counted pulses and the number of previously counted pulses, and may increase the frequency of the frequency modulation signal FMS if the number of currently counted pulses is greater than the number of previously counted pulses.

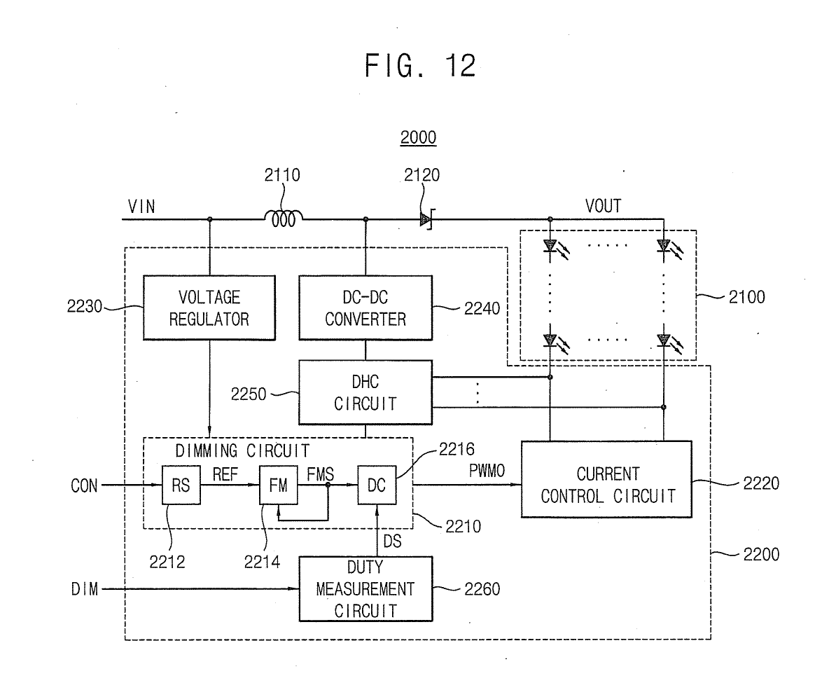

The duty cycle control unit 1300 may generate a pulse width modulation (PWM) output signal PWMO by adjusting a duty cycle of the frequency modulation signal FMS. As will be described below with reference to FIG. 12, the duty cycle control unit 1300 may adjust the duty cycle of the frequency modulation signal FMS based on a duty cycle information signal DS that includes duty cycle information of a dimming signal and is provided from an external circuit.

A light source device may include a light source unit that generates light and a light source driver that drives the light source unit. The light source driver may include a driving voltage generation unit configured to generate a driving voltage for driving the light source unit and an operation control unit that controls an operation of the light source unit. In a conventional LED light source device using a plurality of LEDs as a light source and using a conventional dimming circuit with a PWM driving technique, a load of the driving voltage generation unit and a load of the light source unit may rapidly change, particularly if the plurality of LEDs are simultaneously turned on or off. Such a rapid load change may cause a large ripple, which may result in an audible noise.

To reduce this audible noise, the plurality of LEDs may be driven using a phase shifting technique as well as the PWM driving technique. The phase shifting technique may divide a frame into a plurality of sub-frames, and may drive respective portions of the plurality of LEDs on a sub-frame basis. Accordingly, the rapid load change of the driving voltage generation unit may be prevented. The phase shifting technique may be classified into a sequential manner that sequentially drives the plurality of LEDs and a non-sequential manner that drives the plurality of LEDs regardless of the order of arrangement of the LEDs. The conventional sequential phase shifting technique may deteriorate an electro-migration intensity (EMI) characteristic due to a frequency overlap phenomenon, and the conventional non-sequential phase shifting technique may include a complicated dimming circuit.

The dimming circuit 1000, according to example embodiments, may adjust the frequency of the frequency modulation signal FMS whenever the counting operation is completed, and may generate the PWM output signal PWMO having a variable frequency based on the frequency modulation signal FMS. Since the LEDs are driven using the PWM output signal PWMO of which the frequency changes whenever the counting operation is completed, a dominant noise component, or a noise component having a peak level may be dispersed, thereby improving the EMI characteristic. Further, because the noise component is dispersed, the audible noise may be reduced.

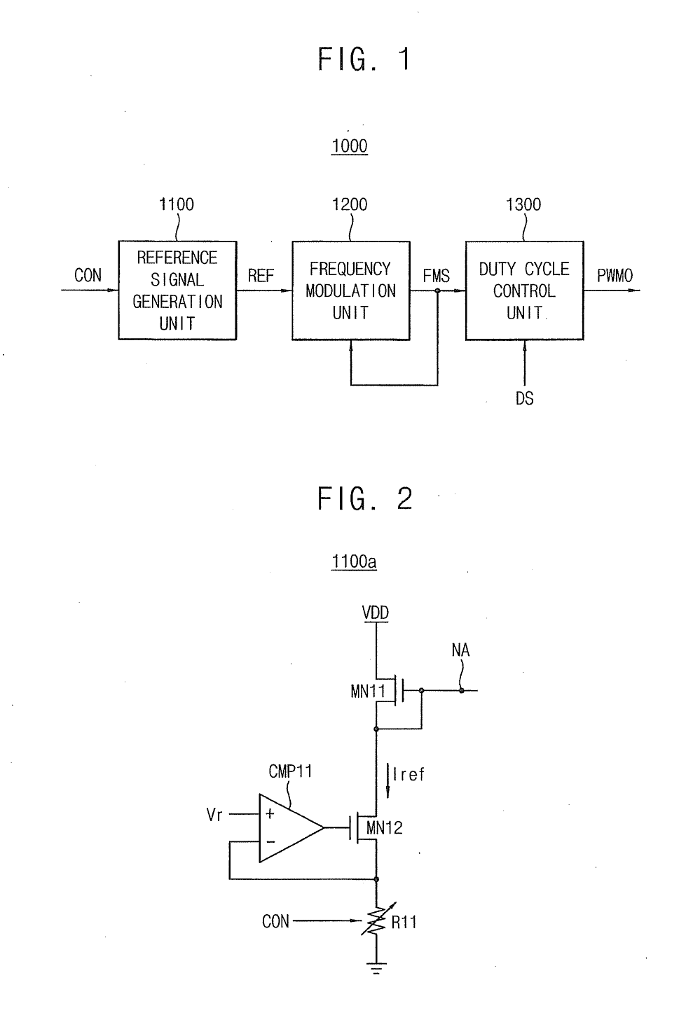

FIG. 2 is a circuit diagram illustrating an example of a reference signal generation unit included in a dimming circuit of FIG. 1.

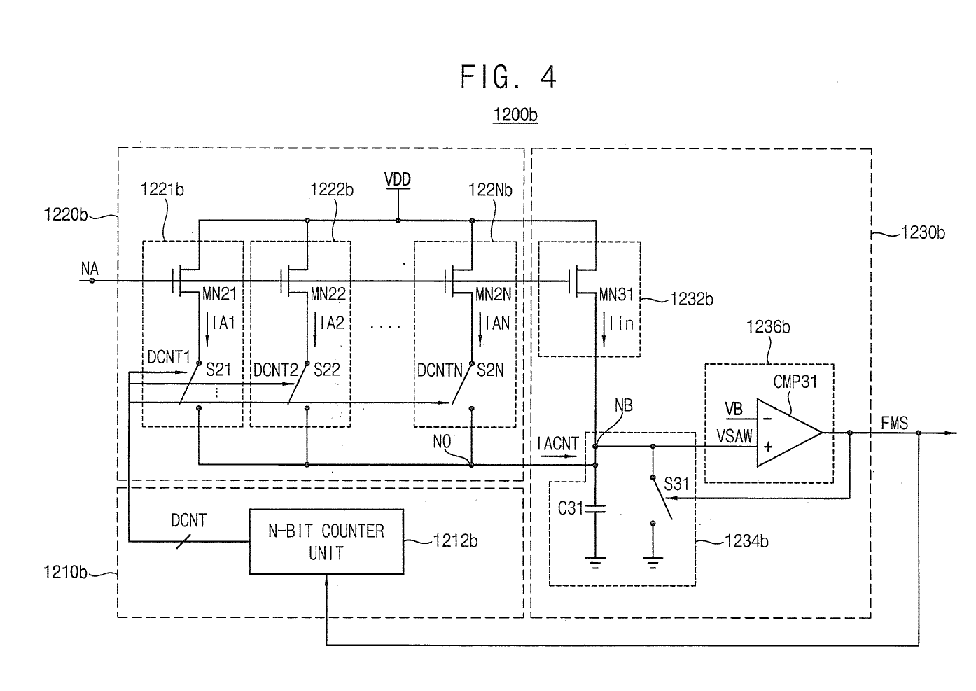

Referring to FIG. 2, a reference signal generation unit 1100a may include a first transistor MN11, a comparator CMP11, a second transistor MN12 and a variable resistor R11. The first transistor MN11 may include a first electrode coupled to a power supply voltage VDD, and a gate and a second electrode that are electrically coupled to each other. As will be described below with reference to FIG. 4, the gate of the first transistor MN11 may be coupled to a frequency modulation unit 1200 of FIG. 1 via a first node NA, and the first transistor MN11 may form a current mirror with some components included in the frequency modulation unit 1200.

The comparator CMP 11 may include a first input terminal to which a regulation voltage Vr is applied, a second input terminal and an output terminal. In at least one example embodiment, the first input terminal may be a non-inverting input terminal, and the second input terminal may be an inverting input terminal. The regulation voltage Vr may be a reference voltage having a desired (or, alternatively, a predetermined) voltage level. The regulation voltage Vr may be provided from an internal circuit of the LED driver including a dimming circuit 1000 of FIG. 1, or may be provided from an external circuit.

The second transistor MN12 may include a third electrode coupled to the second electrode of the first transistor MN11, a gate coupled to the output terminal of the comparator CMP11, and a fourth electrode coupled to the second input terminal of the comparator CMP11. The variable resistor R11 may be coupled between the fourth electrode of the second transistor MN12 and a ground voltage. A resistance of the variable resistor R11 may be adjusted in response to a control signal CON. In at least one example embodiment, the variable resistor R11 may be disposed outside of the LED driver.

The reference signal generation unit 1100a illustrated in FIG. 2 may generate a reference signal Iref by adjusting the resistance of the variable resistor R11 based on the control signal CON. The reference signal Iref may be a current signal. A current level of the reference signal Iref may be determined according to sizes (or channel width (W) and/or channel length (L)) of the transistors MN11 and MN12 as well as the resistance of the variable resistor R11. As will be described below with reference to FIG. 4, the frequency modulation unit 1200 of FIG. 1 may provide currents signals for generating the frequency modulation signal FMS using the current mirror that mirrors the reference signal.

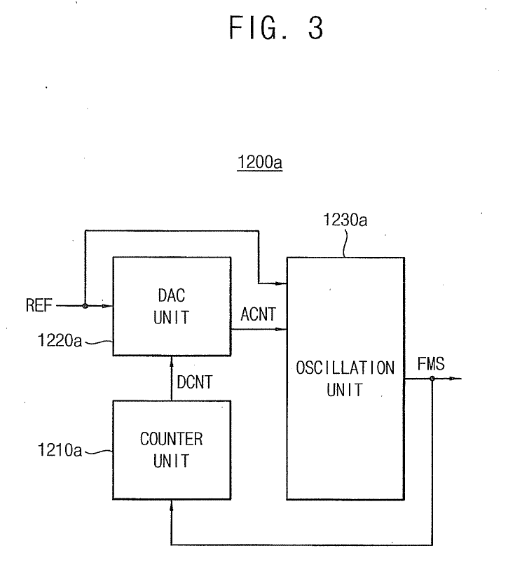

FIG. 3 is a block diagram illustrating an example of a frequency modulation unit included in a dimming circuit of FIG. 1.

Referring to FIG. 3, a frequency modulation unit 1200a may include a counter unit 1210a, a digital-to-analog conversion unit 1220a and an oscillation unit 1230a. The counter unit 1210a may repeatedly perform a counting operation that counts one or more pulses of a frequency modulation signal FMS, and may generate a digital count signal DCNT whenever the counting operation is completed. In at least one example embodiment, the digital count signal DCNT may be an N-bit digital signal, where N is an integer equal to or greater than 1, and a value of the digital count signal DCNT may increase or decrease by “1” whenever the counting operation is completed.

The digital-to-analog conversion unit 1220a may convert the digital count signal DCNT into an analog count signal ACNT based on the reference signal REF. In at least one example embodiment, the analog count signal ACNT may be a current signal or a voltage signal. The oscillation unit 1230a may generate the frequency modulation signal FMS with an initial frequency based on the reference signal REF, and may adjust the frequency of the frequency modulation signal FMS based on the reference signal REF and the analog count signal ACNT.

In at least one example embodiment, a level of the analog count signal ACNT may increase as the value of the digital count signal DCNT increases, and the frequency of the frequency modulation signal FMS may increase as the level of the analog count signal ACNT increases. Further, the level of the analog count signal ACNT may decrease as the value of the digital count signal DCNT decreases, and the frequency of the frequency modulation signal FMS may decrease as the level of the analog count signal ACNT decreases.

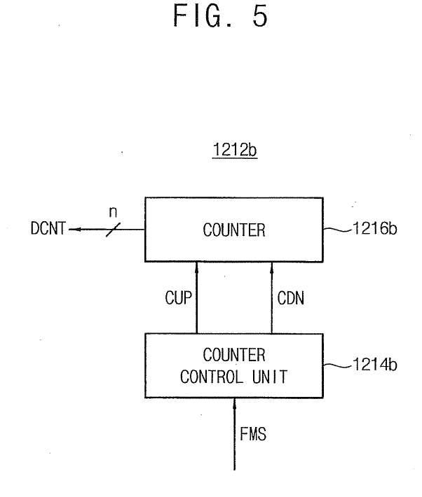

FIG. 4 is a diagram illustrating another example of a frequency modulation unit included in a dimming circuit of FIG. 1, and FIG. 5 is a diagram illustrating an example of an N-bit counter unit included in a counter unit illustrated in FIG. 4.

Referring to FIG. 4, a frequency modulation unit 1200b may include a counter unit 1210b, a digital-to-analog conversion unit 1220b and an oscillation unit 1230b. The counter unit 1210b may include an N-bit counter unit 1212b. The N-bit counter unit 1212b may repeatedly perform a counting operation that counts at least one pulse of a frequency modulation signal FMS, and may generate an N-bit digital count signal DCNT based on the counting operation. For example, the N-bit counter unit 1212b may increase or decrease the value of the N-bit digital count signal DCNT by 1 whenever each counting operation is completed. The digital count signal DCNT may include a plurality of bits DCNT1, DCNT2 and DCNTN. A first bit DCNT1 may correspond to a least significant bit (LSB), and an N-th bit DCNTN may correspond to a most significant bit (MSB).

Referring to FIG. 5, the N-bit counter unit 1212b may include a counter control unit 1214b and a counter 1216b. The counter control unit 1214b may repeatedly perform the counting operation that counts the pulses of the frequency modulation signal FMS, and may selectively generate an up count signal CUP for increasing the value of the digital count signal DCNT or a down count signal CDN for decreasing the value of the digital count signal DCNT whenever each counting operation is completed. For example, the counter control unit 1214b may selectively activate one of the up count signal CUP and the down count signal CDN whenever each counting operation is completed.

In at least one example embodiment, the counter control unit 1214b may repeatedly count a desired (or, alternatively, a predetermined) number of pulses of the frequency modulation signal FMS, and may selectively activate one of the up count signal CUP and the down count signal CDN after every desired number of pulses of the frequency modulation signal FMS. In other example embodiments, the counter, control unit 1214b may repeatedly and periodically count the pulses of the frequency modulation signal FMS with a fixed period, may compare the number of currently counted pulses and the number of previously counted pulses, and may selectively activate one of the up count signal CUP and the down count signal CDN based on the comparison result. For example, if the number of currently counted pulses is greater than the number of previously counted pulses, the down count signal CDN may be activated. If the number of currently counted pulses is smaller than the number of previously counted pulses, the up count signal CUP may be activated. If the number of currently counted pulses is equal to the number of previously counted pulses, both of the up count signal CUP and the down count signal CDN may be deactivated.

The counter 1216b may increase the value of the digital count signal DCNT in response to the up count signal CUP, or may decrease the value of the digital count signal DCNT in response to the down count signal CDN. For example, if the up count signal CUP is activated, the counter 1216b may increase the value of the digital count signal DCNT by 1, and, if the down count signal CDN is activated, the counter 1216b may decrease the value of the digital count signal DCNT by 1. In at least one example embodiment, the counter 1216b may include a plurality of cascade-connected flip-flops.

In at least one example embodiment, the digital count signal DCNT may have a maximum value and a minimum value. The counter control unit 1214b may activate the up count signal CUP whenever each counting operation is completed until the digital count signal DCNT reaches the maximum value. After the digital count signal DCNT reaches the maximum value, the counter control unit 1214b may activate the down count signal CDN whenever each counting operation is completed until the digital count signal DCNT reaches the minimum value. If the digital count signal DCNT reaches the minimum value, the counter control unit 1214b may reactivate the up count signal CUP whenever each counting operation is completed until the digital count signal DCNT reaches the maximum value. Therefore, the counter 1216b may repeatedly increase or decrease the value of the digital count signal DCNT between the maximum value and the minimum value. Accordingly, as will be described below, the frequency of the frequency modulation signal FMS may be increased or decreased according to the value of the digital count signal DCNT.

Although an example embodiment where the counter control unit 1214b and the counter 1216b are separated is illustrated in FIG. 5, the N-bit counter unit 1212b according to example embodiments may be implemented with one block that serves as the counter control unit 1214b and the counter 1216b.

Referring again to FIG. 4, the digital-to-analog conversion unit 1220b may be coupled to a reference signal generation unit 1100a of FIG. 2 via first node NA in a current mirror manner. The digital-to-analog conversion unit 1220b may generate an analog count signal IACNT by converting bits DCNT1, DCNT2 and DCNTN of the digital count signal DCNT. For example, the digital-to-analog conversion unit 1220b may convert the DCNT1, DCNT2 and DCNTN of the digital count signal DCNT into bit current signals IA1, IA2 and IAN, respectively, and may generate the analog count signal IACNT by adding the bit current signals IA1, IA2 and IAN. In at least one example embodiment, the analog count signal IACNT may be a current signal.

The digital-to-analog conversion unit 1220b may include a plurality of bit current generation units 1221b, 1222b and 122Nb and an output node NO. The plurality of bit current generation units 1221b, 1222b and 122Nb may generate the bit current signals IA1, IA2 and IAN according to logic levels of the bits DCNT1, DCNT2 and DCNTN of the digital count signal DCNT, respectively. For example, the first bit current generation unit 1221b may generate the first bit current signal IA1 according to the logic level of the first bit DCNT1. At the output node NO, the bit current signals IA1, IA2 and IAN may be added, and may be provided as the analog count signal IACNT.

Each bit current generation unit 1221b, 1222b and 122Nb may include one transistor MN21, MN22 and MN2N and one switch S21, S22 and S2N. Each transistor MN21, MN22 and MN2N may include a first electrode coupled to a power supply voltage VDD, a gate coupled to the reference signal generation unit 1100a of FIG. 2, and a second electrode. Each transistor MN21, MN22 and MN2N may be coupled to the reference signal generation unit 1100a in a current mirror manner. Each switch S21, S22 and S2N may selectively couple the second electrode of a corresponding one of the transistors MN21, MN22 and MN2N to the output node NO according to the logic level of a corresponding one of the bits DCNT1, DCNT2 and DCNTN of the digital count signal DCNT.

For example, the first bit current generation unit 1221b may include the first transistor MN21 and the first switch S21. The first electrode of the first transistor MN21 may be coupled to the power supply voltage VDD, the gate of the first transistor MN21 may be coupled to the first node NA. Therefore, the first transistor MN21 may form a current mirror with a transistor MN11 included in the reference signal generation unit 1100a of FIG. 2. The first switch S21 may selectively couple the second electrode of the first transistor MN21 to the output node NO according to the logic level of the first bit DCNT1 of the digital count signal DCNT.

In at least one example embodiment, the bit current signals IA1, IA2 and IAN may have different maximum levels from each other according to the corresponding bits DCNT1, DCNT2 and DCNTN of the digital count signals DCNT. For example, if all of the bits DCNT1, DCNT2 and DCNTN have a first logic level, the bit current signals IA1, IA2 and IAN may have substantially the same level of about 0. However, if all of the bits DCNT1, DCNT2 and DCNTN have a second logic level, the bit current signals IA1, IA2 and IAN may have different levels from each other. In at least one example embodiment, a level of each bit current signal IA1, IA2 and IAN may be exponentially proportional to an order of the corresponding one of bits DCNT1, DCNT2 and DCNTN. The first logic level may correspond to a logic low level, and the second logic level may correspond to a logic high level.

For example, if the first bit DCNT1, which may be an LSB, has the second logic level, the level of the first bit current IA1 may be a first current level. The first current level may be determined according to a size ratio (or channel width (W) and/or channel length (L) ratio) of the first transistor MN11 to the transistor MN11 included in the reference signal generation unit 1100a of FIG. 2.

For example, if the first transistor MN11 has substantially the same size as the transistor MN11 included in the reference signal generation unit 1100a of FIG. 2, the first current level may be substantially the same as a current level of a reference signal Iref that flows through the transistor MN11. If the second bit DCNT2 has the second logic level, the level of the second bit current IA2 may be a second current level, which may be twice the first current level. If the N-th bit DCNTN has the second logic level, the level of the N-th bit current IAN may be an N-th current level, which may be 2^{N-1} times the first current level.

The oscillation unit 1230b may include an initial frequency signal generation unit 1232b, a saw signal generation unit 1234b and a frequency modulation signal generation unit 1236b. The initial frequency signal generation unit 1232b may be coupled to the reference signal generation unit 1100a of FIG. 2 via the first node NA in a current mirror manner. For example, the initial frequency signal generation unit 1232b may form a current mirror with the reference signal generation unit 1100a of FIG. 2. The initial frequency signal generation unit 1232b may generate an initial frequency signal Iin for determining an initial frequency of the frequency modulation signal FMS based on the reference signal Iref that is mirrored by the current mirror.

The initial frequency signal generation unit 1232b may include a transistor MN31. The transistor MN31 may include a first electrode coupled to the power supply voltage VDD, a gate coupled to the signal generation unit 1100a of FIG. 2 via the first node NA, and a second electrode coupled to a second node NB. A current level of the initial frequency signal Iin may be determined according to a size ratio of the transistor MN31 of initial frequency signal generation unit 1232b to the transistor MN11 of the reference signal generation unit 1100a of FIG. 2.

The saw signal generation unit 1234b may generate a saw signal VSAW based on the initial frequency signal Iin, the analog count signal IANT and the frequency modulation signal FMS. The saw signal generation unit 1234b may include a capacitor C31 and a switch S31. The capacitor C31 may be coupled between the second node NB and a ground voltage, and the switch S31 may selectively couple the second node NB to the ground voltage in response to the frequency modulation signal FMS.

The frequency modulation signal generation unit 1236b may generate the frequency modulation signal FMS based on the saw signal VSAW and a bias signal VB. The saw signal VSAW and the bias signal VB may be voltage signals. The frequency modulation signal generation unit 1236b may include a comparator CMP31. The comparator CMP31 may generate the frequency modulation signal FMS by comparing the saw signal VSAW and the bias signal VB.

For example, if the saw signal VSAW is lower than the bias signal VB, the comparator CMP31 may generate the frequency modulation signal FMS having a logic low level, and, if the saw signal VSAW is equal to or higher than the bias signal VB, the comparator CMP31 may generate the frequency modulation signal FMS having a logic high level. The bias signal VB may be provided from an internal circuit of the LED driver including the dimming circuit 1000 of FIG. 1, or may be provided from an external circuit.

When the oscillation unit 1230b initially operates, the capacitor C31 may be discharged, the switch S31 may be opened, and the current level of the analog count signal IACNT may be about 0. If the initial frequency signal Iin and the analog count signal IACNT are generated and applied to the second node NB, the capacitor C31 may be charged, and thus a voltage of the second node NB may increase. If the voltage of the second node VB increases above a voltage level of the bias voltage VB, a logic level of the frequency modulation signal FMS may transition from a logic low level to a logic high level. And then, the switch S31 may be closed in response to the frequency modulation signal FMS having the logic high level. Therefore, the voltage of the second node NB may decrease. This charging and discharging of the capacitor C31 may be repeated, as a result the saw signal VSAW may be generated at the second node VB.

If the counter unit 1210b increases the value of the digital count signal DCNT, the current level of the analog count signal IACNT may be increased, and the capacitor C31 may be relatively rapidly increased. Accordingly, the frequency of the saw signal VSAW may be increased. If the counter unit 1210b decreases the value of the digital count signal DCNT, the current level of the analog count signal IACNT may be decreased, and the capacitor C31 may be relatively slowly increased. Accordingly, the frequency of the saw signal VSAW may be decreased. Further, the frequency of the frequency modulation signal FMS may be increased or decreased as the frequency of the saw signal VSAW is increased or decreased.

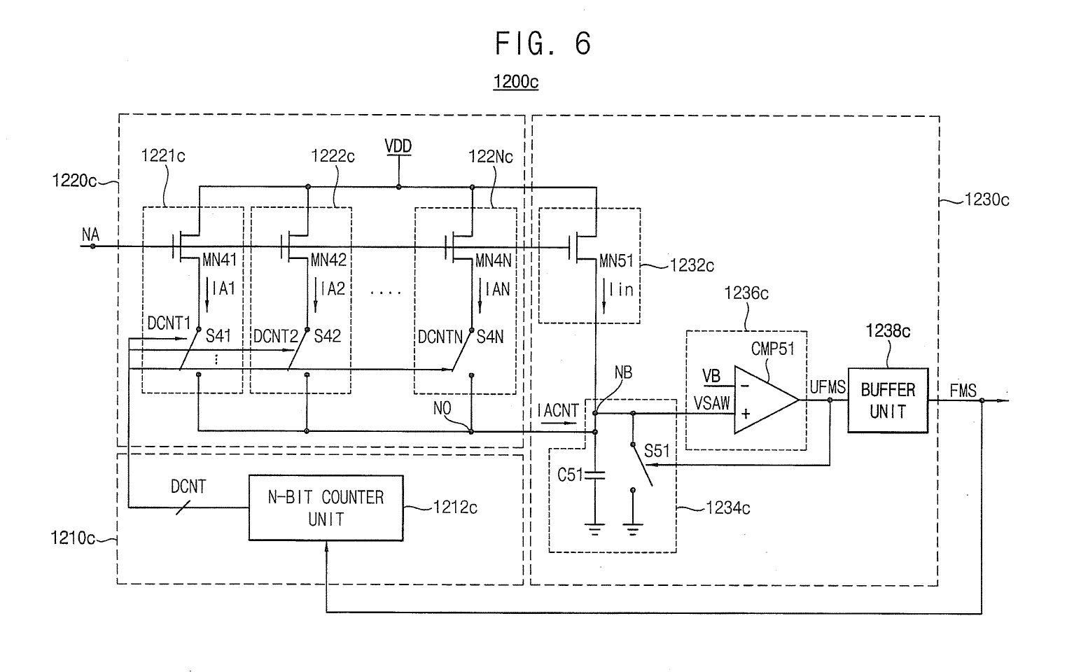

FIG. 6 is a diagram illustrating still another example of a frequency modulation unit included in a dimming circuit of FIG. 1.

Referring to FIG. 6, a frequency modulation unit 1200c includes a counter unit 1210c, a digital-to-analog conversion unit 1220c and an oscillation unit 1230c. The counter unit 1210c may include an N-bit counter unit 1212c. The digital-to-analog conversion unit 1220c may include a plurality of bit current generation units 1221c, 1222c and 122Nc, each of which includes one transistor MN41, MN42 and MN4N and one switch S41, S42 and S4N, and an output node NO. The oscillation unit 1230c may include an initial frequency signal generation unit 1232c including a transistor MN51, a saw signal generation unit 1234c including a capacitor C51 and a switch S51, and a frequency modulation signal generation unit 1236c including a comparator CMP51. The frequency modulation unit 1200c, compared to a frequency modulation unit 1200b of FIG. 4, may further include a buffer unit 1238c in the oscillation unit 1230c. A duplicate description about the components similar to those of the frequency modulation unit 1200b of FIG. 4 will be omitted.

The saw signal generation unit 1234c may generate a saw signal VSAW based on an initial frequency signal Iin, an analog count signal IACNT and an unbuffered frequency modulation signal UFMS. The switch S51 may selectively couple a second node NB to a ground voltage in response to the unbuffered frequency modulation signal UFMS. The frequency modulation signal generation unit 1236c may generate the unbuffered frequency modulation signal UFMS based on the saw signal VSAW and a bias signal VB.

The buffer unit 1238c may buffer the unbuffered frequency modulation signal UFMS provided from the frequency modulation signal generation unit 1236c to output a frequency modulation signal FMS. In at least one example embodiment, the buffer unit 1238c may include at least one inverter.

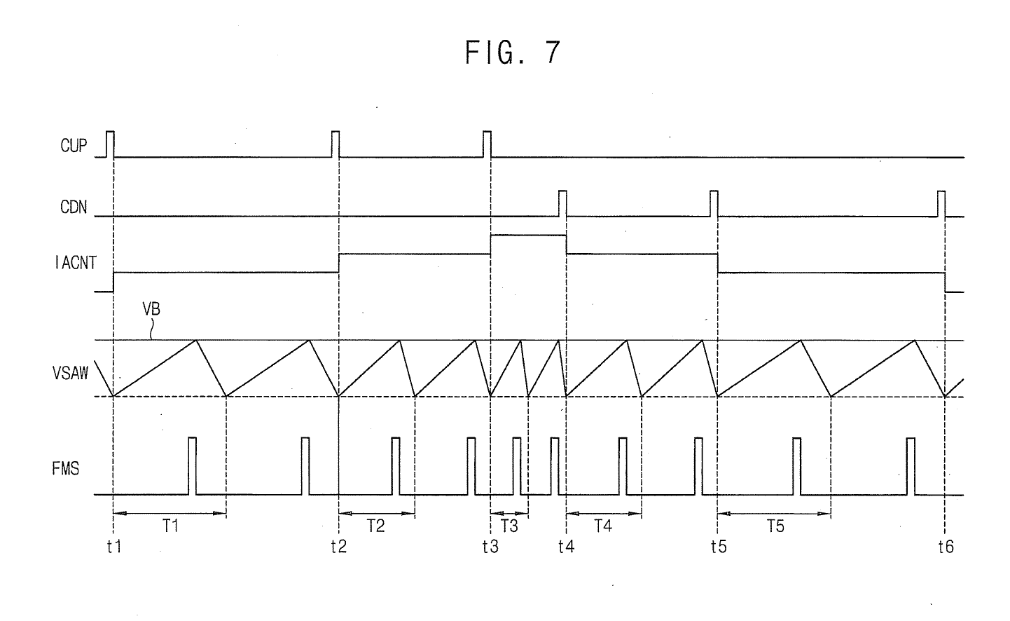

FIG. 7 is a timing diagram illustrating an operation of a dimming circuit according to example embodiments. FIG. 7 illustrates an example embodiment where the dimming circuit adjusts a frequency of a frequency modulation signal FMS after every two pulses of the frequency modulation signal FMS.

Referring to FIGS. 4 and 7, a capacitor C31 may be charged based on an initial frequency signal Iin and an analog count signal IACNT, and the capacitor C31 may be discharged by a switch S31 based on the frequency modulation signal FMS. This charging and discharging of the capacitor C31 may be repeated, and thus a saw signal VSAW may be generated. In the example embodiment illustrated in FIG. 7, once the frequency of the frequency modulation signal FMS is adjusted, this charging and discharging may be performed twice until the next adjustment of the frequency of the frequency modulation signal FMS is performed. The frequency modulation signal generation unit 1236b may generate the frequency modulation signal FMS by comparing the saw signal VSAW and the bias signal VB. While the saw signal VSAW is lower than a bias signal VB, the frequency modulation signal FMS may have a logic low level. While the saw signal VSAW is equal to or higher than the bias signal VB, the frequency modulation signal FMS may have a logic high level.

During a first time interval between a first time t1 and a second time t2, the frequency modulation signal FMS may have a first period T1. If two pulses of the frequency modulation signal FMS are counted, an up count signal CUP may be activated, and a digital count signal DCNT may be increased by 1. Accordingly, a level of an analog count signal IACNT may be increased at the second time t2.

Because the level of the analog count signal IACNT has been increased at the second time t2 compared to that during the first time interval, the capacitor C31 may be relatively rapidly charged during a second time interval between the second time t2 and a third time t3 compared to the first time interval. Accordingly, the frequency modulation signal FMS may have a second period T2 that is shorter than the first period T1, and the frequency of the frequency modulation signal FMS may be increased. If two subsequent pulses of the frequency modulation signal FMS are counted, the up count signal CUP may be activated, and the digital count signal DCNT may be increased by 1. Accordingly, the level of the analog count signal IACNT may be further increased at the third time t3.

During a third time interval between the third time t3 and a fourth time t4, the capacitor C31 may be further rapidly charged, the frequency modulation signal FMS may have a third period T3 that is shorter than the second period T2, and the frequency of the frequency modulation signal FMS may be further increased. The level of the analog count signal IACNT during the third time interval may be the maximum level corresponding to the maximum value of the digital count signal DCNT. If the digital count signal DCNT has the maximum value, the down count signal CDN may be activated and the digital count signal DCNT may be decreased by 1 after two subsequent pulses of the frequency modulation signal FMS are counted. Accordingly, the level of the analog count signal IACNT may be decreased at the fourth time t4.

Because the level of the analog count signal IACNT has been decreased at the fourth time t4 compared to that during the third time interval, the capacitor C31 may be slowly charged during a fourth time interval between the fourth time t4 and a fifth time t5 compared to the third time interval. Accordingly, the frequency modulation signal FMS may have a fourth period T4 that is longer than the third period T3, and the frequency of the frequency modulation signal FMS may be decreased. If two subsequent pulses of the frequency modulation signal FMS are counted, the down count signal CDN may be activated, and the digital count signal DCNT may be decreased by 1. Accordingly, the level of the analog count signal IACNT may be further decreased at the fifth time t5.

During a fifth time interval between the fourth time t4 and a fifth time t5, the capacitor C31 may be further slowly charged, the frequency modulation signal FMS may have a fifth period T5 that is longer than the fourth period T4, and the frequency of the frequency modulation signal FMS may be further decreased. If two subsequent pulses of the frequency modulation signal FMS are counted, the down count signal CDN may be activated, and thus the level of the analog count signal IACNT may be further decreased at the sixth time t6.

As described above, the frequency of the frequency modulation signal FMS may be adjusted (e.g., increased or decreased) whenever each counting operation that counts two pulses is completed. Accordingly, a frequency of a PWM output signal PWMO that is generated based on the frequency modulation signal FMS may be also adjusted.

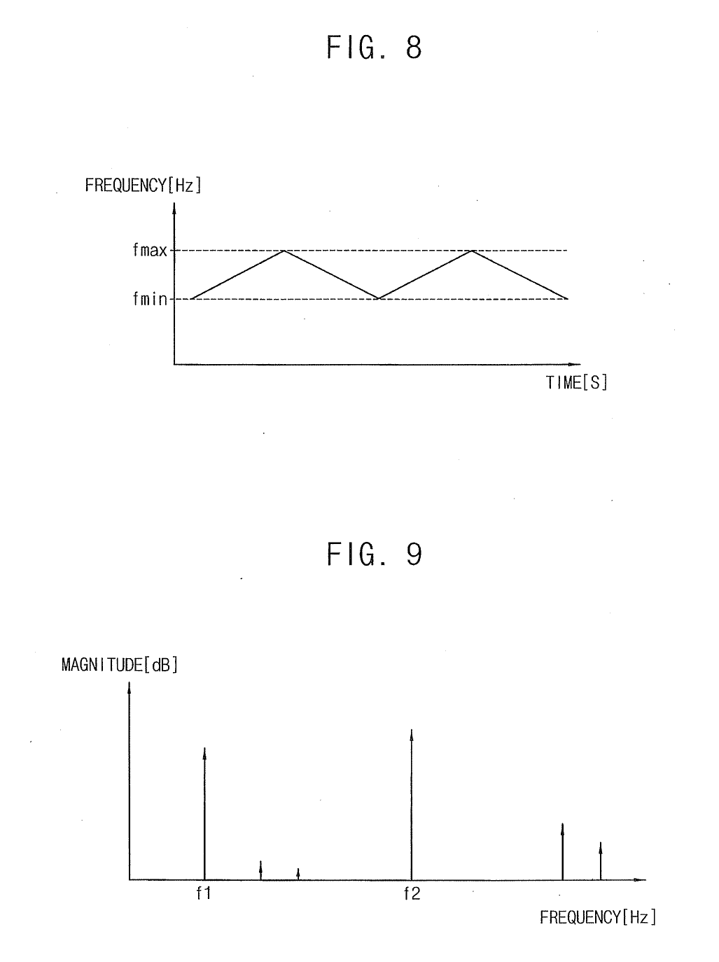

FIG. 8 is a graph illustrating a change in a frequency of a PWM output signal output from a dimming circuit over time according to example embodiments.

Referring to FIGS. 1, 3 and 8, because a PWM output signal PWMO may be generated by adjusting a duty cycle of a frequency modulation signal FMS, the frequency of the PWM output signal PWMO may be substantially the same as that of the frequency modulation signal FMS.

An initial frequency of the frequency modulation signal FMS, or an initial frequency of the PWM output signal PWMO may have the minimum frequency value fmin. A frequency modulation unit 1200 may increase a value of a digital count signal DCNT, and thus may increase a level of an analog digital count ACNT. Accordingly, the frequency of the frequency modulation signal FMS, or the frequency of the PWM output signal PWMO may be increased. The frequency modulation unit 1200 may continuously increase the frequency of the PWM output signal PWMO until the value of the digital count signal DCNT reaches the maximum value, or until the frequency of the PWM output signal PWMO has the maximum frequency value fmax.

After the frequency of the PWM output signal PWMO has the maximum frequency value fmax, the frequency modulation unit 1200 may decrease the value of the digital count signal DCNT, and thus may decrease the level of the analog digital count ACNT. Accordingly, the frequency of the frequency modulation signal FMS, or the frequency of the PWM output signal PWMO may be decreased. The frequency modulation unit 1200 may continuously decrease the frequency of the PWM output signal PWMO until the value of the digital count signal DCNT reaches the minimum value, or until the frequency of the PWM output signal PWMO has the minimum frequency value fmin.

As described above, the frequency modulation unit 1200 may repeatedly increase the frequency of the PWM output signal PWMO until the frequency of the PWM output signal PWMO has the maximum frequency value fmax, or may repeatedly decrease the frequency of the PWM output signal PWMO until the frequency of the PWM output signal PWMO has the minimum frequency value fmin.

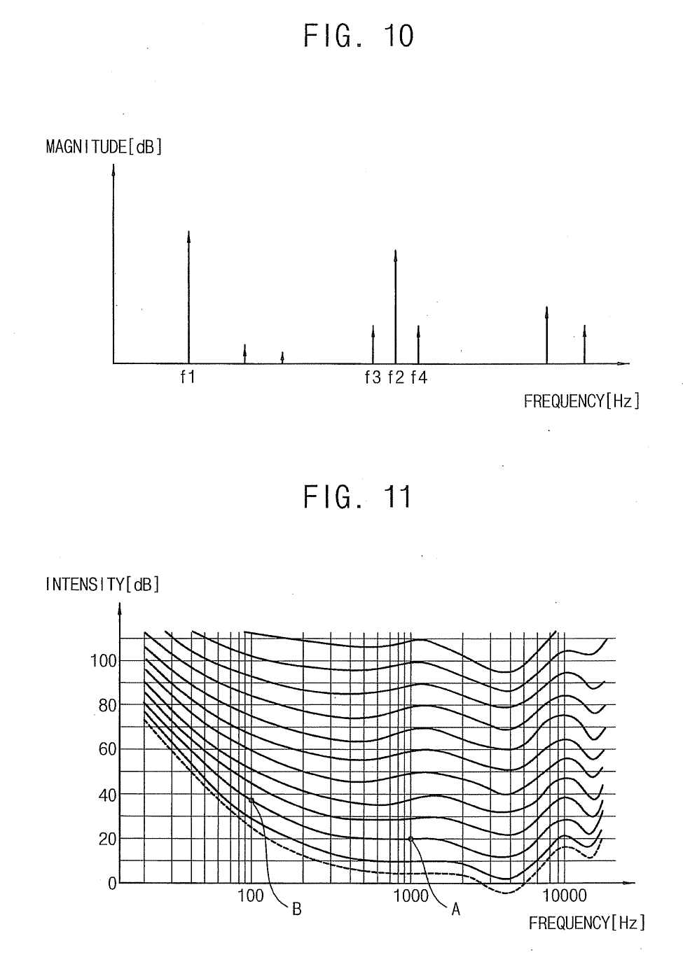

FIGS. 9 and 10 are graphs illustrating an example of a spectral distribution of a noise signal included in a PWM output signal output from a dimming circuit according to at least one example embodiment. FIG. 9 illustrates a spectral distribution about a noise of a PWM output signal output from a conventional dimming circuit, and FIG. 10 illustrates a spectral distribution about a noise of a PWM output signal output from a dimming circuit according to example embodiments.

Referring to FIG. 9, the conventional dimming circuit outputs a PWM output signal having a fixed frequency. As illustrated in FIG. 9, a first noise component having a second frequency f2 may have the highest peak level, and a second noise component having a first frequency f1 may have the second highest peak level. For example, the first noise component may be a dominant noise component, and an EMI characteristic of an LED driver may be deteriorated and an audible noise may be caused due to the first noise component.

Referring to FIG. 10, the dimming circuit according to example embodiments outputs a PWM output signal having a variable frequency that is repeatedly adjusted as illustrated in FIG. 8. Because the PWM output signal has the variable frequency, the first noise component may be dispersed into adjacent frequencies f3 and f4 as well as the second frequency f2, and thus first noise component may have a relatively low peak level. Accordingly, the second noise component having the first frequency f1 may have the highest peak level, and may be the dominant noise component. Because the dominant noise component has a relatively low peak level compared to that of the conventional dimming circuit, an EMI characteristic of an LED driver may be improved, and an audible noise may be reduced as will be described below with reference to FIG. 11.

FIG. 11 is a graph illustrating an equal loudness curve according to a frequency. Each equal loudness curve illustrated in FIG. 11 may represent sound pressure levels that are perceived as the same volume by an auditory organ of a human according to a frequency. For example, the auditory organ of the human may perceive that a sound signal A having an intensity of about 20 dB and a frequency of about 1,000 Hz has the same volume as a sound signal B having an intensity of about 37 dB and a frequency of about 100 Hz. Typically, an audible frequency band may be from about 50 Hz to about 20 kHz. In particular, the auditory organ of the human may be sensitive to a sound signal having a frequency from about 1 kHz to about 5 kHz, and may be insensitive to a sound signal having a frequency lower than about 1 kHz or higher than about 5 kHz.

An operation frequency of a dimming circuit with a PWM driving technique may typically be from about 200 Hz to about 20 kHz. As illustrated in FIG. 10, if a frequency of a dominant noise component is decreased or increased by dispersing a noise component having a peak level into adjacent frequencies, the frequency of the dominant noise component may be adjusted into a frequency to which the auditory organ of the human is insensitive, or out of the audible frequency band, thereby reducing the audible noise.

FIG. 12 is a block diagram illustrating an LED light source device including a dimming circuit according to example embodiments.

Referring to FIG. 12, an LED light source device 2000 includes an LED light source module 2100 and an LED driver 2200. The LED light source device 2000 may further include an inductor 2110 and a zener diode 2120. The LED light source device 2000 may have an input voltage VIN and an output voltage VOUT. The output voltage may be a voltage output from the zener diode 2120 and provide an input to the LED light source module 2100.

The LED light source module 2100 may include a plurality of LEDs arranged in a matrix form. Brightness of the LED light source module 2100 may be determined according to an amount of a current flowing through the plurality of LEDs. The LED driver 2200 may control the current flowing through the LEDs based on a PWM output signal PWMO having a variable frequency. The LED driver 2200 may include a dimming circuit 2210 and a current control circuit 2220. The dimming circuit 2210 may be a dimming circuit 1000 of FIG. 1.

The dimming circuit 2210 may include a reference signal generation unit 2212 configured to generate a reference signal REF for determining an initial frequency of a frequency modulation signal FMS based on a control signal CON, a frequency modulation unit 2214 that repeatedly counts at least one pulse of the frequency modulation signal FMS and adjusts the frequency of the frequency modulation signal FMS whenever each count operation is completed, and a duty cycle control unit 2216 that generates the PWM output signal PWMO having the adjusted frequency (i.e. a variable frequency) by adjusting a duty cycle of the frequency modulation signal FMS. In at least one example embodiment, the counting operation may be performed such that a desired (or, alternatively, a predetermined) number of pulses are counted by each counting operation.

The current control unit 2220 may control the current flowing through the LEDs based on the PWM output signal PWMO. For example, if a duty cycle of the PWM output signal PWMO is long, the amount of the current flowing through the LEDs may be large, and thus the brightness of the LED light source module 2100 may be increased. If a duty cycle of the PWM output signal PWMO is short, the amount of the current flowing through the LEDs may be small, and thus the brightness of the LED light source module 2100 may be decreased.

In at least one example embodiment, the current control unit 2220 may adjust the brightness of the LED light source module 2100 by controlling a plurality of currents flowing through a plurality of columns of the LEDs, respectively. Although FIG. 12 illustrates the current control unit 2220 controls the current based on one PWM output signal PWMO, in at least one example embodiment, the dimming circuit 2210 may generate a plurality of PWM output signals respectively corresponding to the columns of the LEDs, and the current control unit 2220 may control the currents flowing through the columns of the LEDs based on the plurality of PWM output signals, respectively.

The LED driver 2200 may further include a voltage regulator 2230, a direct current (DC)-DC converter 2240, a dynamic headroom control (DHC) circuit and a duty measurement circuit 2260. The voltage regulator 2230 may generate voltage signals used in internal circuits of the LED driver 2200 based on an input voltage VIN. For example, the voltage regulator 2230 may generate a regulation voltage Vr and a bias voltage VB used in the dimming circuit 2210.

The DC-DC converter 2240 may generate a driving voltage VOUT for driving the LEDs included in the LED light source module 2100 based on the input voltage VIN. The inductor 2110 and the zener diode 2120 may be used for the DC-DC converter 2240 to convert a voltage, or may be used to block an inverse current that flows into the DC-DC converter 2240 or an external circuit. The DHC circuit 2250 may sense a voltage applied to the LEDs to provide a voltage information signal to the DC-DC converter 2240, thereby optimizing an operation of the current control circuit 2220.

The duty measurement circuit 2260 may generate a duty cycle information signal DS based on a dimming signal DIM. In at least one example embodiment, the dimming signal DIM may be a PWM signal provided from an external circuit, and the duty cycle control unit 2216 may adjust the duty cycle of the frequency modulation signal FMS based on the duty cycle information signal DS.

In at least one embodiment, the LED light source device 2000 may employ a local dimming technique, in which the LED light source module 2100 may be divided into a plurality of regions, and the LED driver 2200 controls a plurality of currents flowing through the plurality of regions, respectively.

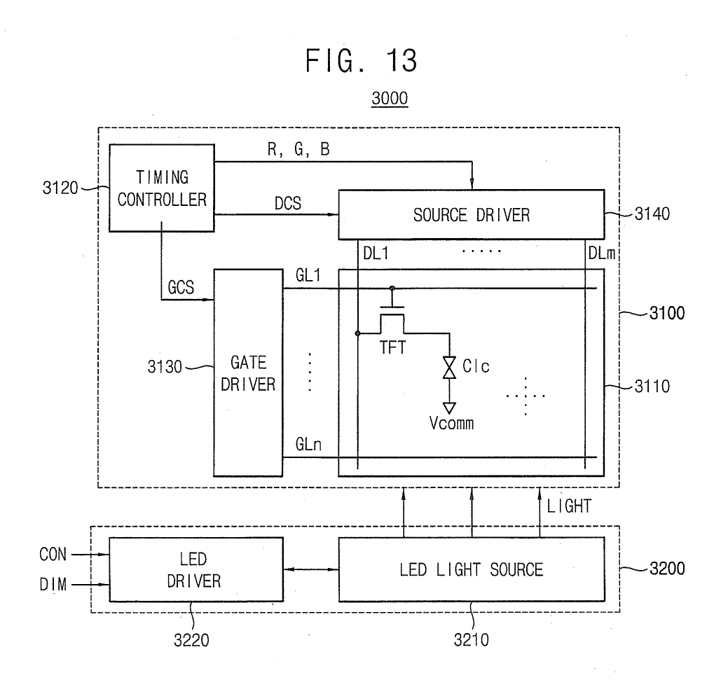

FIG. 13 is a block diagram illustrating a display device including an LED light source device according to example embodiments.

Referring to FIG. 13, a display device 3000 includes an image display device 3100 and an LED light source device 3200. The image display device 3100 may include a liquid crystal display (LCD) panel 3110, a timing controller 3120, a gate driver 3130 and a source driver 3140. Although not illustrated, the image display device 3100 may further include a gray level voltage generation circuit and a display driving voltage generation circuit.

The LCD panel may include a pixel matrix where pixels may be formed at cross points of gate lines GL1 and GLn and data lines DL1 and DLm. Each pixel may include a liquid crystal (LC) cell Clc configured to adjust an intensity of transmitted light according to a gray level voltage and a thin film transistor (TFT) that drives the LCD cell. In at least one example embodiment, the TFT may be turned on in response to a gate-on voltage provided through the gate lines GL1 and GLn, and may provide the LC cell Clc with the gray level voltage provided through the data lines DL1 and DLm. Further, the TFT may be turned off in response to a gate-off voltage provided through the gate lines GL1 and GLn, and thus the gray level voltage charged in the LC cell Clc may be maintained.

The LC cell Clc may be equivalently represented by a capacitor, and may include a common electrode and a pixel electrode coupled to the TFT at either side of the liquid crystal. The LC cell Clc may further include a storage capacitor (not shown) for maintaining the gray level voltage during one frame. The LC cell Clc may adjust light transmittance by changing an arrangement of the liquid crystal based on the gray level voltage provided via the TFT.

The timing controller 3120 may generate a gate control signal GCS for controlling the gate driver 3130 and a data control signal DCS for controlling the source driver 3140. The timing controller 3120 may provide an image signal R, G and B to the source driver 3140. In at least one example embodiment, the gate control signal GCS may include a vertical sync signal, a gate clock signal, an output enable signal, etc., and the data control signal DCS may include a horizontal sync signal, a load signal, an inversion signal, a data clock signal, etc. The gate driver 3130 may sequentially provide the gate-on voltage and the gate-off voltage to the gate lines GL1 and GLn based on the gate control signal provided from the timing controller 3120.

The source driver 3140 may be sequentially provided with the image signal R, G and B from the timing controller 3120 based on the data control signal DCS provided from the timing controller 3120. The source driver 3140 may select the gray level voltage corresponding to the image signal R, G and B, and may provide the selected gray level voltage to the date lines DL1 and DLm. In some embodiments, the gate driver 3130 and the source driver 3140 may be mounted on the LCD panel in a tape carrier package (TCP) form, or may be directly mounted on the LCD panel in a chip on glass (COG) manner.

The LED light source device 3200 may be an LED light source device of FIG. 12. The LED light source device 3200 may include an LED light source module 3210 and an LED driver 3220. The LED light source module 3210 may include a plurality of LEDs arranged in a matrix form. The LED driver 3220 may receive a control signal CON and a dimming signal DIM, and may control a current flowing through the LEDs based on a PWM output signal PWMO having a variable frequency by performing a counting operation to adjust the brightness of the LED light source module 3210. The LED driver 3220 may include a dimming circuit 1000 of FIG. 1.

As described above, an LED light source device and a display device including a dimming circuit according to example embodiments may adjust the brightness of an LED light source based on a PWM output signal having a variable frequency that is adjusted whenever each counting operation is completed, thereby dispersing a noise component having a peak level. Accordingly, an EMI characteristic may be improved, an audible noise may be reduced, and a performance of the display device may be improved.

Example embodiments may be applied to any light source device, any display device and any electronic device including the display device. For example, example embodiments may be applied to a desktop computer, a laptop computer, a digital camera, a video camcorder, a cellular phone, a smart phone, a personal digital assistant (PDA), a navigation system, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

While example embodiments have been particularly shown and described, it will be understood by one of ordinary skill in the art that variations in form and detail may be made therein without departing from the spirit and scope of the claims.

What is claimed is:

1. A dimming circuit, the dimming circuit comprising:
a reference signal generation unit configured to generate a reference signal;
a frequency modulation unit configured to generate a frequency modulation signal having an initial frequency based on the reference signal and a control signal, the frequency modulation unit is configured to repeatedly perform a counting operation, the counting operation counts at least one pulse of the frequency modulation signal, and the frequency modulation unit is configured to adjust the frequency of the frequency modulation signal if the counting operation is completed; and
a duty cycle control unit configured to generate a pulse width modulation output signal by adjusting a duty cycle of the frequency modulation signal.

2. The dimming circuit of claim 1, wherein the frequency modulation unit comprises:
a counter unit configured to generate a digital count signal by performing the counting operation, and configured to adjust a value of the digital count signal if the counting operation is completed;
a digital-to-analog conversion unit configured to convert the digital count signal into an analog count signal based on the reference signal; and
an oscillation unit configured to generate the frequency modulation signal having the initial frequency based on the reference signal, and configured to adjust the frequency of the frequency modulation signal based on the reference signal and the analog count signal.

3. The dimming circuit of claim 2, wherein
the counter unit activates an up count signal and de-activates a down count signal if a number of pulses associated with a previous count operation is less than a number of pulses associated with a current count operation;
the counter unit activates the down count signal and de-activates the up count signal if the number of pulses associated with the previous count operation is greater than the number of pulses associated with the current count operation;
the counter unit de-activates the up count signal and the down count signal if the number of pulses associated with the previous count operation is equal to the number of pulses associated with the current count operation;
the digital count signal increases if the up count signal is activated and the down count signal is de-activated;
the digital count signal decreases if the down count signal is activated and the up count signal is de-activated; and
the digital count signal remains the same if the up count signal is de-activated and the down count signal is de-activated.

4. The dimming circuit of claim 3, wherein
a level of the analog count signal increases as the value of the digital count signal increases,
the frequency of the frequency modulation signal increases as the level of the analog count signal increases,
the level of the analog count signal decreases as the value of the digital count signal decreases, and
the frequency of the frequency modulation signal decreases as the level of the analog count signal decreases.

5. The dimming circuit of claim 3, wherein the counter unit comprises:
a counter control unit configured to perform the counting operation, and if the counting operation is complete, the counter control unit is configured to generate one of an up count signal to increase the value of the digital count signal and a down count signal to decrease the value of the digital count signal; and
a counter configured to increase the value of the digital count signal based on the up count signal, and configured to decrease the value of the digital count signal based on the down count signal.

6. The dimming circuit of claim 5, wherein
the digital count signal has a maximum value and a minimum value,
the counter control unit activates the up count signal until the value of the digital count signal reaches the maximum value, and
if the value of the digital count signal reaches the maximum value, the counter control unit activates the down count signal until the value of the digital count signal reaches the minimum value.

7. The dimming circuit of claim 3, wherein the digital-to-analog conversion unit comprises:
a plurality of bit current generation units configured to generate a plurality of bit current signals, each bit current generation unit is configured to generate a corresponding one of the plurality of bit current signals based on a corresponding one of a plurality of bits of the digital count signal; and
an output node configured to provide the analog count signal based on the plurality of bit current signals.

8. The dimming circuit of claim 7, wherein a level of each bit current signal is exponentially proportional to an order of the corresponding one of the plurality of bits of the digital count signal.

9. The dimming circuit of claim 7, wherein the bit current generation unit comprises:
a transistor including a first electrode coupled to a power supply voltage, a gate coupled to the reference signal generation unit, and a second electrode, the transistor is a current mirror with the reference signal generation unit; and
a switch configured to selectively couple the second electrode of the transistor to the output node based on a logic level of the corresponding one of the plurality of bits of the digital count signal.

10. The dimming circuit of claim 3, wherein the oscillation unit comprises:
an initial frequency signal generation unit configured to generate an initial frequency signal based on the reference signal;
a saw signal generation unit configured to generate a saw signal based on the initial frequency signal, the analog count signal and the frequency modulation signal; and
a frequency modulation signal generation unit configured to generate the frequency modulation signal based on the saw signal and a bias signal.

11. The dimming circuit of claim 10, wherein the initial frequency signal generation unit comprises:
a transistor including a first electrode coupled to a power supply voltage, a gate coupled to the reference signal generation unit, and a second electrode, the transistor is a current mirror with the reference signal generation unit.

12. The dimming circuit of claim 11, wherein the saw signal generation unit comprises:
a capacitor including a first terminal coupled to the second electrode of the transistor and a second terminal covered to a ground voltage; and
a switch configured to selectively couple the first terminal of the capacitor to the ground voltage based on the frequency modulation signal.

13. The dimming circuit of claim 12, wherein the frequency modulation signal generation unit comprises:
a comparator configured to compare the saw signal and the bias signal, and configured to generate the frequency modulation signal having a first logic level if the saw signal is lower than the bias signal and a second logic level if the saw signal is equal to or greater than the bias signal.

14. The dimming circuit of claim 10, wherein the oscillation unit further comprises:
a buffer unit configured to buffer the frequency modulation signal, and to output the buffered frequency modulation signal.

15. The dimming circuit of claim 1, wherein the reference signal generation unit comprises:
a first transistor including a first electrode connected to a power supply voltage, and a gate and a second electrode that are connected to each other;
a comparator including a first input terminal to which a regulation voltage is applied, a second input terminal, and an output terminal;
a second transistor including a third electrode coupled to the second electrode of the first transistor, a gate connected to the output terminal of the comparator, and a fourth electrode connected to the second input terminal of the comparator; and
a variable resistor connected between the fourth electrode of the second transistor and a ground voltage, the variable resistor having a resistance that varies in response to the control signal.

16. A frequency modulation unit comprising:
an oscillation unit configured to generate a frequency modulation signal based on a reference signal and a count of pulses in the frequency modulation signal.

17. The frequency modulation unit of claim 15, further comprising:
a counter, unit configured to generate a digital count signal based on the number of pulses, such that a value of the digital count signal is adjusted if a counting operation is completed, wherein the oscillation unit is configured to generate the frequency modulation signal based on the adjusted digital count signal.

18. The frequency modulation unit of claim 17, wherein
if the counting operation is complete, the counter control unit is configured to generate one of an up count signal to increase the value of the digital count signal and a down count signal to decrease the value of the digital count signal.

19. The frequency modulation unit of claim 15, further comprising:
a digital-to-analog conversion unit including,
a plurality of bit current generation units configured to generate a plurality of bit current signals, each bit current generation unit is configured to generate a corresponding one of the plurality of bit current signals based on a corresponding one of a plurality of bits of the digital count signal; and
an output node configured to provide an analog count signal based on the plurality of bit current signals, wherein the oscillation unit is configured to generate the frequency modulation signal based on the analog count signal.

20. A light emitting diode (LED) driver comprising:
a dimming circuit configured to generate a pulse width modulation output signal having a variable frequency, the dimming circuit includes,
a reference signal generation unit configured to generate a reference signal, the reference signal is configured to determine an initial frequency of a frequency modulation signal, the frequency modulation signal is based on a control signal,
a frequency modulation unit configured to generate the frequency modulation signal having the initial frequency based on the reference signal, the frequency modulation circuit is configured to repeatedly perform a counting operation, the counting operation counts at least one pulse of the frequency modulation signal, and the frequency modulation circuit is configured to adjust the frequency of the frequency modulation signal if the counting operation is completed, and
a duty cycle control unit configured to generate the pulse width modulation output signal by adjusting a duty cycle of the frequency modulation signal; and
a current control circuit configured to control a current that flows through a LED based on the pulse width modulation output signal.
